(19) United States
(12) Patent Application Publication
(10) Pub. No.: US 2009/0199900 A1
(43) Pub. Date: Aug. 13, 2009

(54) THIN FILM HOLOGRAPHIC SOLAR CONCENTRATOR/COLLECTOR

(75) Inventors: Ion Bita, San Jose, CA (US); Russell Wayne Gruhlke, Milpitas, CA (US); Gang Xu, Cupertino, CA (US); Marc Maurice Mignard, San Jose, CA (US)

Correspondence Address: KNOBBE, MARTENS, OLSON & BEAR, LLP, 2040 MAIN STREET, FOURTEENTH FLOOR, IRVINE, CA, 92614, US

(73) Assignee: QUALCOMM MEMS Technologies, Inc., San Diego, CA (US)

(21) Appl. No.: 12/369,643

(22) Filed: Feb. 11, 2009

Related U.S. Application Data
(60) Provisional application No. 61/028,139, filed on Feb. 12, 2008.

(51) Int. Cl. H01L 31/052; G02B 5/32

(52) U.S. Cl. 136/259; 359/15

(57) ABSTRACT

In various embodiments described herein, a device comprising one or more light guides that is optically coupled to one or more photocells is described. The device further comprises one or more light turning films or layers comprising volume or surface diffractive features or holograms. Light incident on the light guides is turned by volume or surface diffractive features or holograms that are reflective or transmissive and guided through the light guides by multiple total internal reflections. The guided light is directed towards the photocells. In certain embodiments, solar energy is also used to power or heat a thermal generator to heat water or produce electricity from steam. Various embodiments may comprise an air gap or an optical isolation layer disposed between the multiple light guides.

### CROSS-REFERENCE TO RELATED APPLICATIONS

This application claims priority under 35 U.S.C. § 119(e) to U.S. Provisional Application Ser. No. 61/028,139 filed on Feb. 12, 2008, titled “THIN FILM HOLOGRAPHIC SOLAR CONCENTRATOR/COLLECTOR” (Atty. Docket No. QMRC.002PR), which is hereby expressly incorporated herein by reference in its entirety.

### BACKGROUND

1. Field of the Invention

The present invention relates to the field of solar power and more particularly to using micro-structured thin films to collect and concentrate solar radiation.

2. Description of the Related Art

For over a century fossil fuel such as coal, oil, and natural gas has provided the main source of energy in the United States. The need for alternative sources of energy is increasing. Fossil fuels are a non-renewable source of energy that are depleting rapidly. The large scale industrialization of developing nations such as India and China has placed a considerable burden on the available fossil fuel. In addition, geopolitical issues can quickly affect the supply of such fuel. Global warming is also of greater concern in recent years. A number of factors are thought to contribute to global warming, however, widespread use of fossil fuels is presumed to be a main cause of global warming. Thus there is an urgent need to find a renewable and economically viable source of energy that is also environmentally safe. Solar energy is an environmentally safe renewable source of energy that can be converted into other forms of energy such as heat and electricity. However, the use of solar energy as an economically competitive source of renewable energy is hindered by low efficiency in converting light energy into electricity and the variation in the solar energy depending on the time of the day and the month of the year.

Photovoltaic (PV) cells convert optical energy to electrical energy and thus can be used to convert solar energy into electrical power. Photovoltaic solar cells can be made very thin and modular. PV cells can range in size from a few millimeters to 10's of centimeters. The individual electrical output from one PV cell may range from a few milliwatts to a few Watts. Several PV cells may be connected electrically and packaged to produce sufficient amount of electricity. PV cells can be used in wide range of applications such as providing power to satellites and other spacecraft, providing electricity to residential and commercial properties, charging automobile batteries, etc.

Solar concentrators can be used to collect and focus solar energy to achieve higher conversion efficiency in PV cells. For example, parabolic mirrors can be used to collect and focus light on a device that converts light energy in to heat and electricity. Other types of lenses and mirrors can also be used to significantly increase the conversion efficiency.

It may be advantageous to employ light collectors and concentrators that collect and focus light on the PV cell and track the movement of the sun through the day. Additionally it is also advantageous to have the ability to collect diffused light on cloudy days. Such systems, however, are complicated, often bulky and large. For many applications it is also desirable that these light collectors and/or concentrators are compact in size. It may be possible to use holographic thin films as compact solar collectors and/or concentrators.

### SUMMARY

In various embodiments described herein, a device comprising a light guide optically coupled to a photocell is described. The device further comprises a light turning film or layer comprising volume or surface diffractive features or holograms. Light incident on the light guide is turned by volume or surface diffractive features or holograms that are reflective or transmissive and guided through the light guide by multiple total internal reflections. The guided light is directed towards a photocell. In certain embodiments, solar energy is also used to heat a thermal generator to heat water or produce electricity from steam. In various embodiments, the light guide is thin (e.g., less than 1 millimeter) and comprises, for example, a thin film. The light guide may be formed of a flexible material. Multiple light guide layers may be stacked on top of each other to produce concentrators that operate over a wider range of angles and/or wavelengths and that have increased diffraction efficiency.

In various embodiments, a device for collecting solar energy comprising a first light guide having top and bottom surfaces is disclosed. The device further comprises a first photocell and a plurality of diffractive features disposed to redirect ambient light incident on said top surface of the first light guide such that said light is guided in the light guide by total internal reflection from said top and bottom surfaces to said first photocell, wherein said first light guide has a thickness less than or equal to 1 millimeter.

In various embodiments, a device for collecting solar energy comprising a first means for guiding light is disclosed. The light guiding means include top and bottom surfaces and light is guided therein by multiple total internal reflections at said top and bottom surfaces. The device further comprises a first means for absorbing light, said light absorbing means being configured to produce an electrical signal as a result of light absorbed by the light absorbing means. The device also comprises a plurality of means for diffracting light, said light diffracting means disposed to redirect ambient light incident on said top surface of the first light guiding means such that said light is guided in the light guiding means by total internal reflection from said top and bottom surfaces to said first light absorbing means, wherein said first light guiding means has a thickness less than or equal to 1 millimeter. In some embodiments, the light guiding means comprises a light guide, the light absorbing means comprises a photocell or the light diffracting means comprises diffractive features.

In various embodiments, a method of manufacturing a device for collecting solar energy is disclosed. The method comprises providing a first light guide having top and bottom surfaces, said light guide including a plurality of diffractive features and guiding light therein by multiple total internal reflections at said top and bottom surfaces. The method further comprises providing a first photocell, wherein said first light guide has a thickness less than or equal to 1 millimeter. In various embodiments, the plurality of diffractive features is disposed on the first light guide.

In various embodiments, a device for collecting solar energy comprising a first and a second light guide layers guiding light therein is disclosed. The device further comprises a first photocell; a first plurality of diffractive features disposed to redirect ambient light incident on said first light guide layer; and a second plurality of diffractive features disposed to redirect ambient light incident on said second light guide layer, wherein light is guided in said first and second light guide layers to said first photocell.

In various embodiments, a device for collecting solar energy comprising at least one light collector is disclosed. The light collector comprises a light guide having a top and bottom surface and a plurality of diffractive features configured to redirect ambient light incident on said top surface of said light guide, at least one photocell and a solar thermal generator.

In various embodiments, a device for collecting solar energy comprising a light guide having top and bottom surfaces guiding light therein by multiple total internal reflections at said top and bottom surfaces is disclosed. The device further comprises a photocell and a transmissive diffractive element comprising a plurality of diffractive features disposed to redirect ambient light incident on said top surface of the light guide such that said light is guided in the light guide by total internal reflection from said top and bottom surfaces to said first photocell.

In various embodiments, a device for collecting solar energy comprising a means for guiding light, said light guiding means having top and bottom surfaces and guiding light therein by multiple total internal reflections at said top and bottom surfaces is disclosed. The device further comprises a means for absorbing light, said light absorbing means being configured to produce an electrical signal as a result of light absorbed by the light absorbing means. The device also comprises a means for diffracting light by transmission, said light diffracting means comprising a plurality of diffractive features disposed to redirect ambient light incident on said top surface of the light guide such that said light is guided in the light guide by total internal reflection from said top and bottom surfaces to said light absorbing means. In various embodiments, the light guiding means comprises a light guide, the light absorbing means comprises a photocell or the light diffracting means by transmission comprises transmissive diffractive element comprising a plurality of diffractive features.

In various embodiments, a method of manufacturing a device for collecting solar energy is disclosed. The method comprises providing a light guide having top and bottom surfaces, said light guide including a transmissive diffractive element comprising a plurality of diffractive features and guiding light therein by multiple total internal reflections at said top and bottom surfaces and providing a photocell.

In various embodiments, a device for collecting solar energy comprising a first and a second means for guiding light is disclosed. The device further comprises a first means for absorbing light wherein said light absorbing means is configured to produce an electrical signal as a result of light absorbed by the light absorbing means. The device also comprises a first plurality of means for diffracting light and a second plurality of means for diffracting light. The first and second plurality of light diffracting means are configured to redirect ambient light incident on said first and second light guiding means. Light is guided in said first and second light guiding means to said first light absorbing means. In various embodiments, the first and second light guiding means comprise a light guide, the first light absorbing means comprises a photocell and the first and second plurality of light diffracting means comprise diffractive features.

In various embodiments, a method of fabricating a device for collecting solar energy is disclosed. The method comprises providing first and second light guide layers guiding light therein, said first light guide layer including a first plurality of diffractive features therein and said second light guide layer including a second plurality of diffractive features therein. The method further comprises providing a first photocell. In some embodiments, light is guided in said first and second light guide layers to said first photocell. In some embodiments, the first and the second plurality of diffractive features are disposed on said first and second light guide layers.

In various embodiments, a device for collecting solar energy comprising at least one means for collecting light is disclosed. The light collecting means further comprises a means for guiding light, said light guiding means having a top and bottom surface and a plurality of means for diffracting light. The light diffracting means are configured to redirect ambient light incident on said top surface of said light guiding means. The device further comprises at least one means for absorbing light, said light absorbing means being configured to produce an electrical signal as a result of light absorbed by the light absorbing means. The device also comprises a means for converting thermal energy into electrical or mechanical energy. In various embodiments, the light collecting means comprises a light collector, the light guiding means comprises a light guide, the light diffracting means comprises diffractive features, the light absorbing means comprises a photocell or the thermal energy converting means comprises a solar thermal generator.

In various embodiments, a method of manufacturing a device for collecting solar energy is disclosed. The method comprises providing at least one light collector, said light collector comprising a light guide having a top and bottom surface and a plurality of diffractive features configured to redirect ambient light incident on said top surface of said light guide. The method further comprises providing at least one photocell and providing a solar thermal generator.

### BRIEF DESCRIPTION OF THE DRAWINGS

Example embodiments disclosed herein are illustrated in the accompanying schematic drawings, which are for illustrative purposes only.

FIG. 1A schematically illustrates a side view of a light guide wherein a ray of light is refracted inside a light guide and subsequently is transmitted out of the light guide.

FIG. 1B schematically illustrates the side view of a light guide and the cone of refraction.

FIG. 1C schematically illustrates a side view of a light turning element comprising transmission hologram disposed on the upper surface a light guide.

FIG. 1D schematically illustrates a side view of a light turning element comprising reflection hologram disposed on the lower surface of a light guide.

FIG. 2A schematically illustrates a cone of light that is guided within a light guide comprising a light turning element having volume or surface diffractive features or holograms.

FIG. 2B schematically illustrates another embodiment of a light guide comprising a light turning element having volume or surface diffractive features or holograms and two cones of light that are guided within the light guide.

FIG. 3A schematically illustrates an embodiment of a light turning layer comprising volume holograms.

FIG. 3B schematically illustrates an embodiment of a light turning layer comprising surface relief diffractive features.

FIG. 3C schematically illustrates an embodiment of a light turning layer comprising planarized surface relief diffractive features.

FIG. 4A schematically illustrates one arrangement for fabricating a light collector comprising a light turning layer with transmission holograms.

FIG. 4B schematically illustrates a light collector fabricated by method of FIG. 4A and the ambient light collected and guided therein.

FIG. 4C schematically illustrates one arrangement for fabricating a light collector comprising multiple volume holograms.

FIG. 5A schematically illustrates one arrangement for fabricating a light collector comprising a light turning layer with reflection holograms.

FIG. 5B schematically illustrates a light collector fabricated by method of FIG. 5A and the ambient light collected and guided therein.

FIG. 6 schematically illustrates an embodiment comprising multiple light collectors stacked with an air gap between consecutive light collectors.

FIG. 7 schematically illustrates an embodiment comprising multiple light collectors laminated together such that the different light collectors are optically coupled.

FIG. 8 schematically illustrates an embodiment comprising multiple light collectors comprising a low refractive index material between consecutive light collectors.

FIG. 9 and FIG. 9A schematically illustrate an embodiment comprising multiple light collectors wherein each light collector collects light incident at different angles.

FIG. 10 schematically illustrates an embodiment comprising multiple light collectors wherein each light collector collects light at different wavelength.

FIG. 11A schematically illustrates an embodiment comprising a light collector and PV cells disposed laterally along opposing edges of the light collector.

FIGS. 11B-11D schematically illustrate various embodiments of light collectors comprising one, two or four PV cells disposed laterally along edges of the light collectors.

FIG. 12 schematically illustrates a system comprising a light collector, PV cells and a solar thermal generator.

FIG. 13 schematically illustrates a light collecting plate, sheet or film optically coupled to photocells placed on the roof and on the windows of a residential dwelling.

FIG. 14 schematically illustrates an embodiment wherein light collecting plate, sheet or film optically coupled to photocells is placed on the roof of an automobile.

FIG. 15 schematically illustrates a light collecting plate, sheet or film optically coupled to photocells is attached to the body of a laptop.

FIG. 16 schematically illustrates an example of attaching light collecting plate, sheet or film optically coupled to photocells is attached to an article of clothing.

FIG. 17 schematically illustrates an example of placing light collecting plate, sheet or film optically coupled to photocells on shoes.

FIG. 18 schematically illustrates an embodiment wherein light collecting plate, sheet or film optically coupled to photocells is attached to the wings and windows of an airplane.

FIG. 19 schematically illustrates an embodiment wherein light collecting plate, sheet or film optically coupled to photocells is attached to a sail boat.

FIG. 20 schematically illustrates an embodiment wherein light collecting sheet, plate or film optically coupled to photocells is attached to a bicycle.

FIG. 21 schematically illustrates an embodiment wherein light collecting plate, sheet or film optically coupled to photocells is attached to a satellite.

FIG. 22 schematically illustrates an embodiment wherein a light collect sheet that is substantially flexible so as to be rollable is optically coupled to photocells.

### DETAILED DESCRIPTION OF CERTAIN PREFERRED EMBODIMENTS

The following detailed description is directed to certain specific embodiments of the invention. However, the invention can be embodied in a multitude of different ways. As will be apparent from the following description, the embodiments may be implemented in any device that is configured to collect, trap and concentrate radiation from a source. More particularly, it is contemplated that the embodiments described herein may be implemented in or associated with a variety of applications such as providing power to residential and commercial properties, providing power to electronic devices such as laptops, PDAs, wrist watches, calculators, cell phones, camcorders, still and video cameras, mp3 players etc. In addition the embodiments described herein can be used in wearable power generating clothing, shoes and accessories. Some of the embodiments described herein can be used to charge automobile batteries, navigational instruments and pumping water. The embodiments described herein can also find use in aerospace and satellite applications. Still other applications are possible.

In various embodiments described herein, a solar collector and/or concentrator is coupled to a photocell. The solar collector and/or concentrator comprises a light guide, for example, a plate, sheet or film with volume or surface relief diffractive features or holograms formed therein. Ambient light that is incident on the light guide is turned into the light guide by the volume or surface relief diffractive features or holograms and guided through the light guide by total internal reflection. A photocell is disposed along one or more edges of the light guide and light that is emitted out of the light guide is coupled into the photocell. Using the light guide to collect, concentrate and direct ambient light to photocells may realize opto-electric devices that convert light energy into electricity with increased efficiency and lower cost. In certain embodiments, solar energy is also used to power (e.g. heat) a thermal generator to heat water or produce electricity from steam. The light guide may be formed as a plate, sheet or film. In various embodiments, the light guide is thin (e.g., less than 1 centimeter) and comprises, for example, a thin film. The light guide may be fabricated from a rigid or a semi-rigid material. In some embodiments, the light guide may be formed of a flexible material. The light guide may comprise surface and volume diffractive features or holograms that are reflective or transmissive. Multiple light guide layers may be stacked on top of each other to produce concentrators that operate over a wider range of angles and/or wavelengths and that have increased diffraction efficiency.

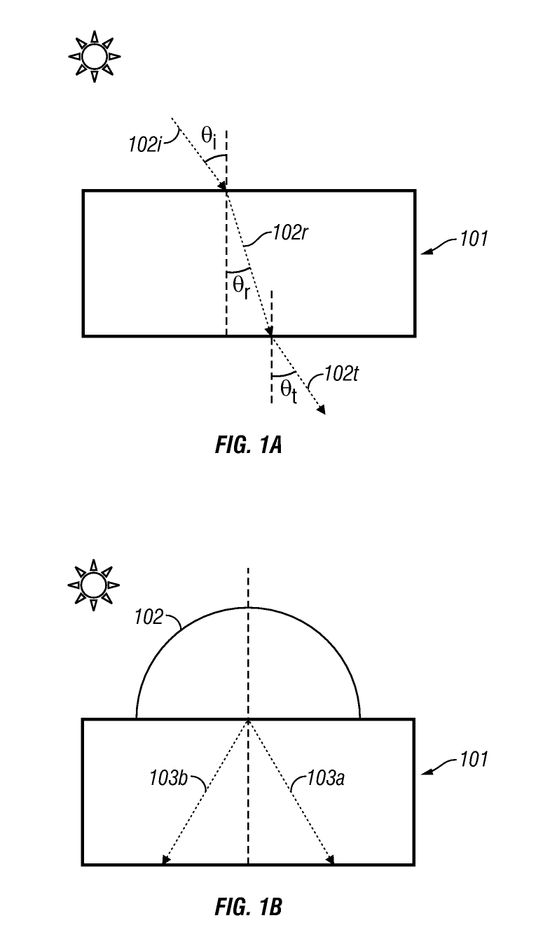

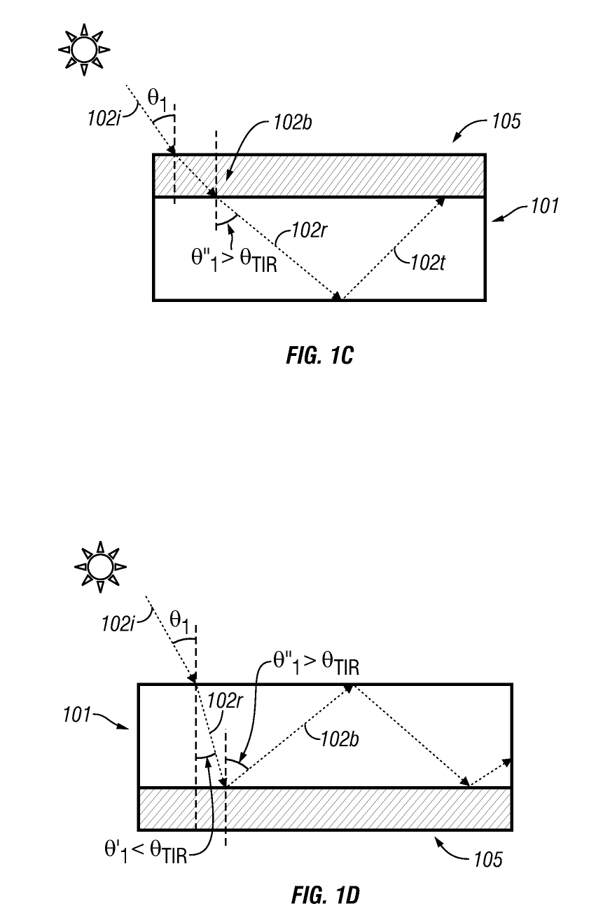

Several embodiments of the invention disclosed herein enable collection of sunlight for delivery at photocells with a flat concentrator apparatus comprising holographic elements. Ambient sunlight is captured by the diffractive or holographic elements and coupled into guided modes of the light guide. FIG. 1A shows a side view of an embodiment comprising a light guide 101 surrounded by air. The light guide 101 may comprise optically transmissive material that is substantially optically transmissive to radiation at one or more wavelengths. For example in one embodiment, the light guide 101 may be substantially optically transmissive to wavelengths in the visible and near infra-red region. In other embodiments, the light guide 101 may be transparent to wavelengths in the ultra-violet or infra-red regions. The light guide 101 may comprise a substantially optically transmissive plate, sheet or film. The light guide 101 may be planar or curved. The light guide 101 may be formed from rigid or semi-rigid material such as glass or acrylic so as to provide structural stability to the embodiment. In other embodiments, the light guide 101 may be formed of flexible material such as a flexible polymer. Other materials for example, PMMA, polycarbonate, polyester (for e.g. PET), cyclo-olefin polymer (for e.g. Zeonor) may be used to form the light guide 101 in several other embodiments. The thickness may in some embodiments determine whether the light guide 101 is rigid or flexible. In certain embodiments, the light guide 101 may comprise a thin film disposed on a substrate. The substrate may be opaque, partially or substantially completely optically transmissive or transparent. The substrate may be rigid or flexible.

The light guide 101 may comprise two surfaces. The upper surface is configured to receive ambient light. In some embodiments, the bottom surface of the light guide may be adhered to a substrate. The light guide 101 may be bounded by a plurality of edges all around. In various embodiments, the length and width of the light guide 101 is substantially greater than the thickness of the light guide 101. The thickness of the light guide 101 may be between 0.1 mm to 10 mm. The area of the light guide 101 may be between 1.0 cm² to 10,000 cm². However, dimensions outside these ranges are possible.

Consider a ray of ambient light 102i that is incident on the upper surface of the embodiment of light guide 101 originating in air as shown in FIG. 1A. The ray 102i is incident at angle θᵢ with respect to the normal to the surface. In some embodiments, the ray 102i will be refracted into the light guide 101 as ray 102r at an angle θᵣ with respect to the normal and will be subsequently transmitted out of the light guide 101 as ray 102t into the surrounding air medium at an angle θₜ with respect to the normal. In some embodiments, the angle θₜ at which the ray 102t is transmitted out of the light guide 101 is approximately equal to the angle θᵢ at which the ray 102i is incident on the light guide 101.

The angle of refraction θᵣ that the refracted ray 102r within the light guide 101 makes with the normal to the light guide 101 can be calculated by Snell's law and is equal to the inverse sine of the ratio of the refractive index of the light guide material to the refractive index of the air medium. In some embodiments, the rays that are incident from air on the light guide 101 and lie in the hemisphere 102, as shown in FIG. 1B, are refracted within the cone defined by rays 103a and 103b and are subsequently transmitted out of the light guide 101. Because the rays of the incident light in these embodiments are almost always transmitted out of the light guide irrespective of the angle of incidence, it may be difficult to use such a light guide to trap and guide light therein.

To prevent the ray of light 102r of FIG. 1A from being transmitted out of the light guide 101, the angle of refraction θᵣ must be greater than or equal to the critical angle θ_{TIR} of the material comprising the light guide 101. The critical angle θ_{TIR} is the smallest angle of incidence at which a ray of light passing from an optically denser medium to an optically rarer medium is totally internally reflected. The critical angle θ_{TIR} depends on the refractive indices of the optically denser and the optically rare media. With reference to FIG. 1A, the critical angle θ_{TIR} thus depends on the material comprising the light guide 101 and the material surrounding the light guide 101 (e.g. air). In some embodiments, it can be shown by Snell's law that, for a ray originating in air (for e.g. as shown in FIG. 1A), the angle of refraction is approximately equal to the critical when the angle of incidence is approximately equal to 90 degrees with respect to the normal to the surface.

A light turning element can be included with a light guide to trap ambient light incident on the light guide and convert this incident light into guided modes of the light guide. The light turning element can turn the angle of the incident ray of light inside the light guide such that the ray of light can be guided within the light guide by total internal reflection. In some embodiments, the amount of light collected and guided by a light guide can be referred to as the light collection efficiency of the light guide. Therefore, in various embodiments, the light turning element can enable and/or increase the light collection efficiency of the light guide. The light collected and guided by the light guide comprising a light turning element may be delivered to one or more opto-electronic devices (e.g. a solar cell) disposed at one or more edges of the light guide. By proper choice of the dimensions and the material comprising the light guide, rays of incident ambient light can be guided through the light guide and delivered at a desired distance.

FIGS. 1C and 1D illustrate embodiments of the light guide 101 further comprising a light turning element 105. The light turning element 105 may be a micro-structured thin film. In some embodiments, the light turning element 105 may comprise volume or surface relief diffractive features or holograms. The light turning element 105 may be a thin plate, sheet or film. The thickness of the light turning element 105 may range from approximately 1 μm to approximately 100 μm in some embodiments but may be larger or smaller in other embodiments. In some embodiments, the thickness of the light turning element or layer 105 may be between 5 μm and 50 μm. In some other embodiments, the thickness of the light turning element or layer 105 may be between 1 μm and 10 μm. The light turning element 105 may be attached to surfaces of the light guide 101 by an adhesive. The adhesive may be index matched with the material comprising the light guide 101. In some embodiments, the adhesive may be index matched with the material comprising the light turning element 105. In some embodiments, the light turning element 105 may be laminated on the light guide 101. In certain other embodiments, volume or surface diffraction features or holograms may be formed on the upper or lower surface of the light guide 101 by embossing, molding, or other process.

The volume or surface diffractive elements or holograms can operate in transmission or reflection mode. The transmissive diffractive element or holograms generally comprise optically transmissive material and diffract light passing there through. Reflection diffractive elements and holograms generally comprise a reflective material and diffract light reflected there from. In certain embodiments, the volume or surface diffractive elements/holograms can be a hybrid of transmission and reflection structures. The diffractive elements/holograms may include rainbow holograms, computer-generated diffractive elements or holograms, or other types of holograms or diffractive optical elements. In some embodiments, reflection holograms may be preferred over transmission holograms because reflection holograms may be able to collect and guide white light better than transmission holograms. In those embodiments, where a certain degree of transparency is required, transmission holograms may be used. Transmission holograms may be preferred over reflection holograms in embodiments that comprise multiple layers. In certain embodiments described below, stacks of transmissive layers (e.g. transmission holograms) can be useful to increase optical performance. Transmissive layer may also be useful in embodiments that are designed to permit some light to pass through the light guide to spatial regions beneath the light guide. The diffractive elements or holograms may also reflect or transmit colors for design or aesthetic purpose. In embodiments, wherein the light guide are configured to transmit one or more colors for design or aesthetic purposes, transmission holograms or rainbow holograms may be used. In embodiments, wherein the light guide may be configured to reflect one or more colors for design or aesthetic purposes, reflection holograms or rainbow holograms may be used.

One possible advantage of the light turning element 105 is explained below with reference to FIGS. 1C and 1D. FIG. 1C shows an embodiment wherein the light turning element 105 comprises a transmission hologram and is disposed on an upper surface of the light guide 101. Ambient ray of light 102i is incident on the top surface of the light turning element 105 at an angle of incidence θ₁. The light turning element 105 turns the direction of the incident ray of light 102i or diffracts it. The diffracted ray of light 102b is incident on the light guide 101 such that the angle of propagation of ray 102r in the light guide 101 is θ″₁ which is greater than θ_{TIR}. Thus the ray of light 102t which is transmitted out of the light guide 101 and is not guided within the light guide 101 in the absence of the light turning element 105 (for e.g. as shown in FIG. 1A) is now collected and guided within the light guide 101 in the presence of the light turning element 105. The light turning element 105 can therefore increase the collection efficiency of the light guide 101.

FIG. 1D illustrates an embodiment wherein the light turning element 105 comprises reflection hologram and is disposed on the bottom surface of the light guide 101. As described previously with reference to FIG. 1A, ray 102i is incident on the upper surface of the light guide 101 at angle θ₁ such that the angle of propagation of ray 102r is θ′₁. The refracted ray 102r upon striking the light turning element 105 is turned by the light turning element 105 as ray 102b at an angle θ″₁ which is greater than the critical angle θ_{TIR} for the light guide 101. Since the angle θ″₁ is greater than the critical angle θ_{TIR}, the ray 102b is subsequently guided within the light guide 101 through multiple total internal reflections. Thus the ray of light 102i that was previously not guided by the light guide 101 (for e.g. as shown in FIG. 1A) is now guided within the light guide 101 because of the presence of the light turning element 105. In some embodiments, the light guide 101 and the light turning element 105 together may be referred to as light collectors or as light collecting film or layer if they comprise a film or layer.

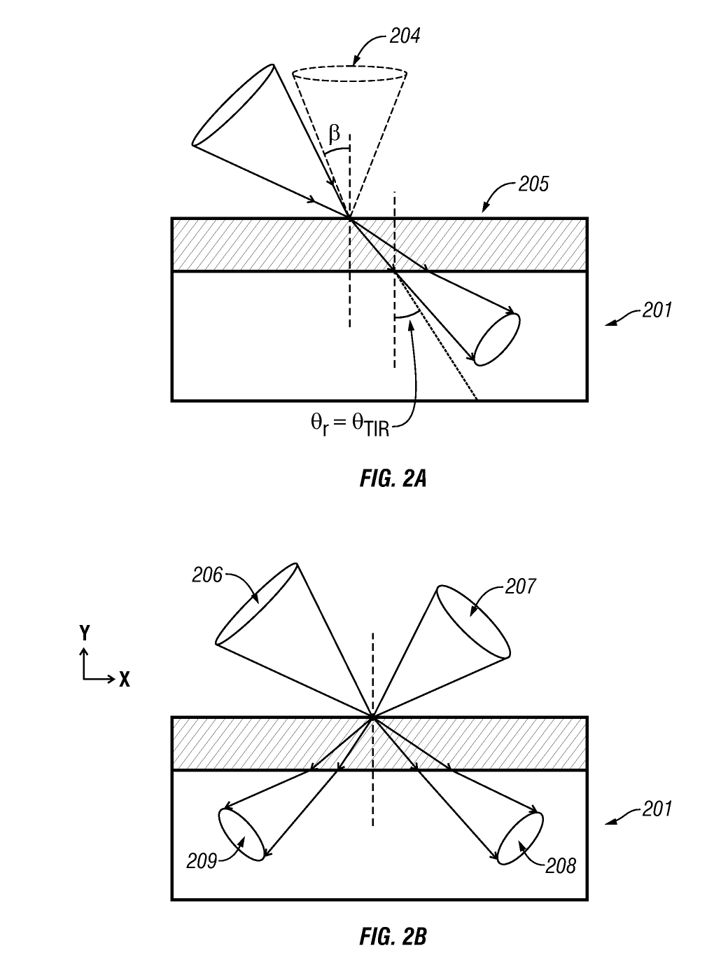

As described above, the light turning element may be used to increase the cone of acceptance, the rays of light lying within being collected and guided by the light guide. FIG. 2A shows an embodiment of a light guide 201 comprising a light turning element 205 having volume or surface diffractive features disposed on an upper surface of the light guide 201. Rays of incident light that lie within cone 204 (henceforth referred to as cone of unguided light) with semi-angle β are turned or bent by the light turning element 205 such that the angle of propagation of the turned or bent rays in the light guide 201 is less than or equal to θ_{TIR}. Therefore, rays of incident light lying within the cone of unguided light 204 may be transmitted out of the light guide. In various embodiments, rays of light lying outside the cone of unguided light 204 may be collected and guided within the light guide as described below with respect to FIG. 2B.

In the light turning element 205, the surface or volume diffractive features or holograms may be formed so as to accept ambient light along different directions. For example in the embodiment illustrated in FIG. 2B, the surface or volume diffraction features can accept and turn rays of incident light within cone 206 that lies in a second geometric quadrant bound by the −x and y axes and cone 207 that lies in the first geometric quadrant bound by the x and y axes. The rays of light within cone 206 are transmitted along paths within cone 208 while the rays of light within cone 207 are transmitted along paths within cone 209. The rays of light within cones 208 and 209 can be guided within light guide 201 and may be coupled in to an opto-electronic device (for e.g. a photocell) that may be disposed along the edges of the light guide 201.

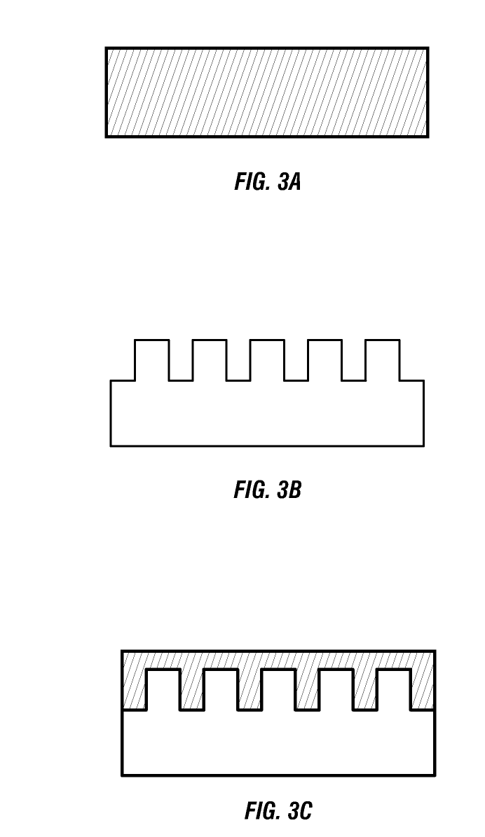

The hologram is fabricated by recording the pattern produced by the interference of two beams on a photosensitive plate, film or layer. One of the two beams is called the input beam and the other is called the output beam. The two beams are interfered and the resultant interference pattern is recorded on the photosensitive plate, film or layer as a modulation in the refractive index (e.g., volume hologram) or as topographical features (e.g., surface hologram). In some embodiments, the interference pattern can be recorded as fringes or grating. In certain embodiments, the interference pattern (or holographic pattern) can be recorded as variation of refractive index. Such features are referred to as volume features (e.g., in volume holograms). FIG. 3A shows the side view of a holographic plate, film or layer comprising volume features. In other embodiments, the interference pattern may be recorded as topographical variation for example on the surface of the holographic plate, film or layer. Such features are referred to as surface relief features (e.g., in surface holograms or diffractive optical elements). FIG. 3B shows the side view of a holographic plate, film or layer comprising surface relief holographic or diffractive features.

To reproduce the second beam, the holographic plate, film or layer can be illuminated by the first beam. In some embodiments, the conversion efficiency of the holographic plate, film or layer can be defined as the ratio of the light output by the holographic plate, film or layer to the light input on the holographic plate, film or layer. In some embodiments, the conversion efficiency of volume holograms may be higher than the conversion efficiency of surface holograms. In certain embodiments, a lower refractive index planarizing material may be disposed over the surface holographic features as shown in FIG. 3C. The planarized surface holograms may advantageously permit additional layers to be formed on the surface hologram and may protect the surface features thereby resulting in a more robust structure. Planarization may also advantageously enable laminating multiple light collecting films together.

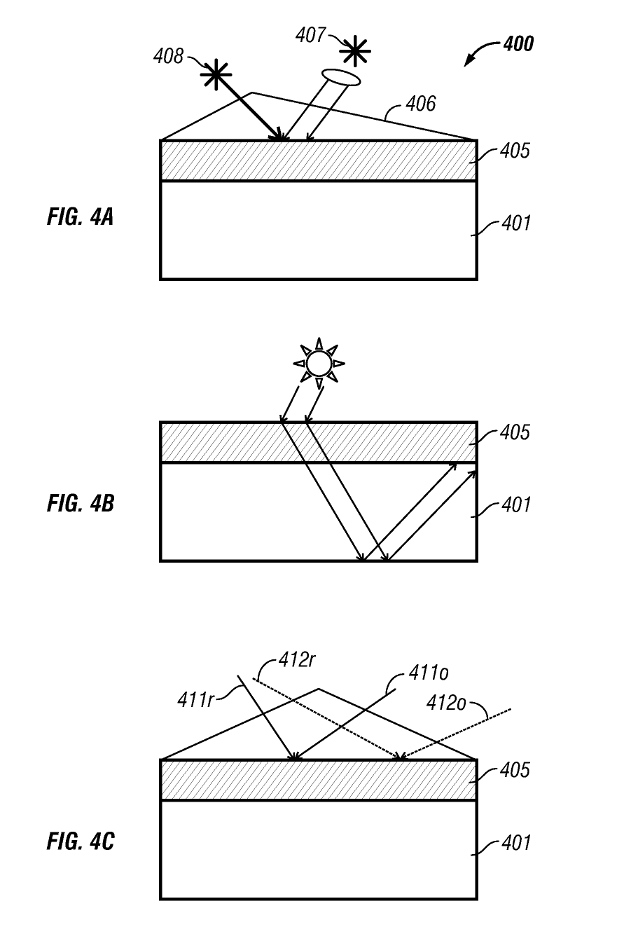

FIG. 4A shows one method of fabricating an embodiment 400 comprising a volume transmission hologram. The method comprises disposing a photosensitive plate, film or layer 405 on the upper surface of a light guide 401. As described above, the photosensitive plate, film or layer 405 may be laminated or adhered to the light guide 401, for example, by an adhesive layer. This adhesive layer may be index-matched to the light guide 401. In other embodiments, the photosensitive material is coated on the light guide 401. In certain embodiments, the photosensitive plate, film or layer 405 may be referred to as a hologram recording material. The photosensitive plate, film or layer 405 may comprise photographic emulsions, dichromated gelatin, photoresists, photothermoplastics, photopolymers, photochromics, photorefractives, etc. In some embodiments, the hologram recording material may comprise a layer of silver halide or other photosensitive chemical. Diffractive features may be formed in the photosensitive material by exposing the photosensitive material to a pattern of light such as an interference pattern.

In certain embodiments for example, the method comprises disposing a first light source 408 and a second light source 407 forward of the light guide 401. A coupling prism 406 is disposed over the hologram recording material 405 such that the beam from the first light source 408 (also referred to as a reference beam) can be incident on the holographic material at steep angles and be a guided mode of the light guide 401. A light beam from the second light source 407 (also referred to as the object beam) is directed towards the holographic recording material through the coupling prism as well. The interference between the object beam and the reference beam is recorded on the hologram recording material. After the photographic plate, film or layer 405 is developed, the embodiment 400 can be used to collect and guide sun light as shown in FIG. 4B. The embodiment 400 when exposed to sunlight will turn rays of sunlight that have approximately the same angle of incidence as the object beam and guide them through the light guide 401. The incident rays of sun are guided within the light guide 401 along the same direction as the guided reference beam.

Multiple holograms can be recorded by changing the angles of the reference beam and the object beam as shown in FIG. 4C. In FIG. 4C, ray 411o represents an object beam incident at a first angle of incidence, while ray 412o represents an object beam incident at a second angle of incidence. Ray 411r and ray 412r represent the reference beams that correspond to the object beams 411o and 412o respectively. Solar rays that are incident at the first angle will be collected and guided through the light guide along the direction of reference beam 411r whereas solar rays that are incident at the second angle will be collected and guided through the light guide along the direction of reference beam 412r. Thus a turning layer comprising multiple holograms can collect and guide solar rays incident at multiple angles.

Multiple holograms can also be recorded by changing the wavelength and/or the angle of incidence of the reference beam. For example, in one embodiment, three different holograms can be recorded for three different wavelengths of the reference beam (for e.g. ultraviolet, blue and green). In some embodiments, the wavelength of the reference beams may be approximately 325 μm, approximately 365 μm, approximately 418 μm and approximately 532 μm. Red lasers may be used as a reference beam if an appropriate recording medium is available. Recording multiple holograms at different wavelengths of the reference beam can be advantageous to collect a broader range of wavelengths of light in the solar spectrum.

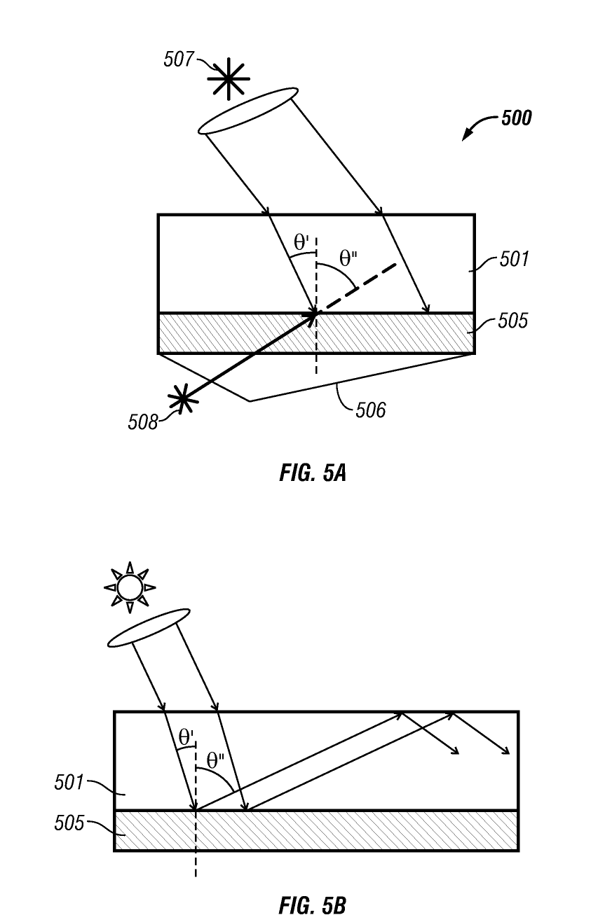

FIG. 5A shows a method of fabricating an embodiment 500 comprising reflection holograms. In this embodiment, the method comprises disposing a photosensitive plate, film or layer 505 on a bottom surface of a light guide 501. The photographic plate, film or layer can be coated on or laminated to the bottom surface of the light guide 501. As described above with reference to FIG. 4A, an adhesive can be used to join the photosensitive plate, film or layer to the light guide 501. The reference laser source 508 is disposed rearward to the light guide 501 such that the reference beam is incident on the bottom surface of the light guide 501. As described above, the reference prism 506 can be used to couple the reference beam at steep angles (for e.g. θ″) to produce a beam that is a guided mode of the light guide 501. A light source 507 is disposed forward of the light guide 501 such that the object beam is incident on the upper surface of the light guide 501. The interference pattern between the object beam emitted from the light source 507 and the reference beam is recorded on the hologram recording material. As shown in FIG. 5B rays of sun that are incident on the light guide 501 at approximately same incident angle as the object beam from light source 507 of FIG. 5A will be guided through the light guide along the direction of the guided reference beam.

Other methods of recording holograms are also possible. For example, in one embodiment a master holographic pattern that produces the desired guided mode can be used to emboss the desired holographic pattern on a turning film or layer or to reproduce the desired holographic pattern via optical methods. The holographic pattern that produces the desired guided mode can also be fabricated by optical methods or by using computer programs (e.g., computer generated holograms).

Light guides comprising light turning elements as fabricated above may be used to collect and concentrate sun light and may hence be referred to as light collectors. While a significant portion of the light incident on these light collectors will be captured, there still remains a portion of the ambient light incident on these light collectors that is not collected and may be directed out of the light collectors thereby reducing the collection efficiency of the light collectors. To improve the light collection efficiency, multiple light collectors can be included in a stack. In some embodiments, a plurality of light collector layers comprise light guides disposed with a light turning element comprising surface or volume diffraction features or holograms, such that the light transmitted through the upper light guiding layers can be received by the lower light guiding layers.

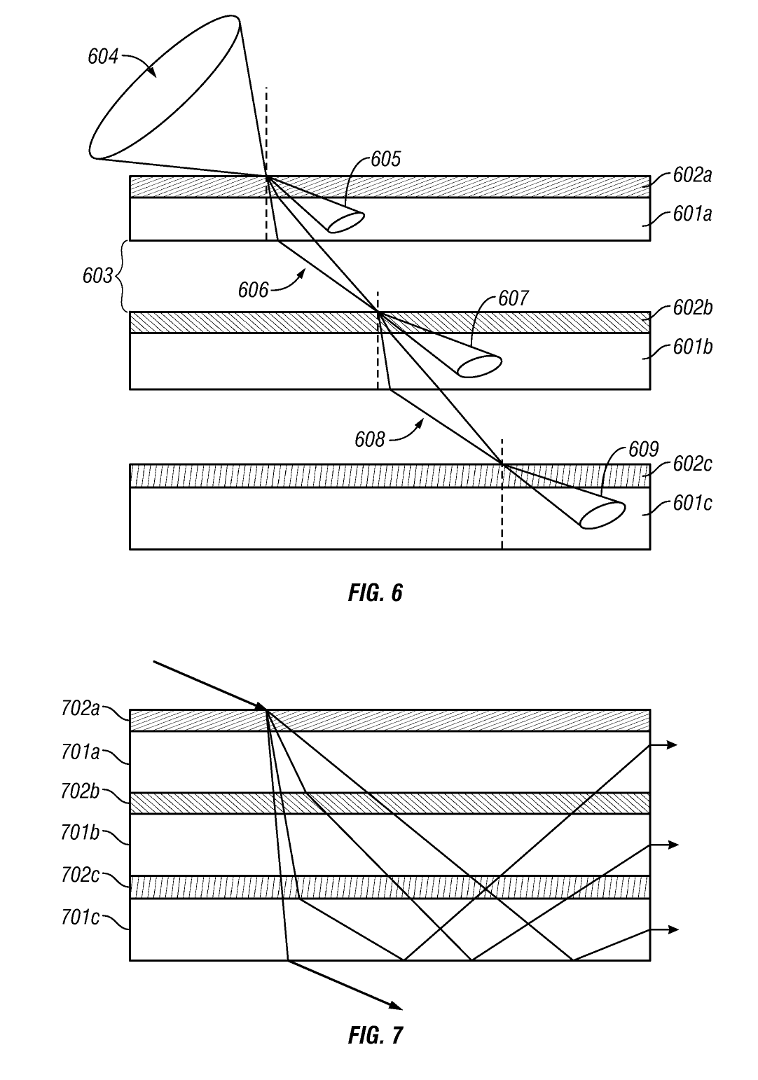

FIG. 6 shows an embodiment comprising three light guide layers 601a, 601b and 601c. The three light guide layers are stacked such that an air gap 603 is included between any two consecutive light guide layers. Light turning elements 602a, 602b and 602c are disposed on surfaces of the light guide layers 601a, 601b and 601c. Each light turning layer comprises volume or surface relief diffractive features that turn light through different angles. For example, in FIG. 6, ambient light within cone 604 is incident on light turning element 602a disposed over light guide 601a. The light turning element 602a may turn the incident light into guided modes. Rays of light that are coupled out of the light turning element 602a at an angle greater than the critical angle, for example lying within cone 605, will be coupled in to the guided modes of light guide 601a. The rays that are directed out of the light turning element 602a at an angle less than the critical angle, for example lying within cone 606, will not be collected and will be incident on light turning element 602b disposed on light guide 601b. The light turning element 602b may turn light incident thereon. Rays of light that are coupled out of the light turning element 602b at an angle greater than the critical angle, for example lying in cone 607, will be coupled into guided modes of the light guide 601b, while the rays of light that are directed out of the light turning element 602b at an angle lesser than the critical angle, for example lying in cone 608, will be coupled out of the light guide 601b. Similarly, the light turning element 602c may turn the light incident thereon. Rays of light that are coupled out of the light turning element 602c at an angle greater than the critical angle, for example lying in cone 609, will be coupled into guided modes of the light guide 601c. Thus, a large portion of the ambient light may be collected by the stack of multiple light guides described above. In some embodiments, the cumulative light collection efficiency of all the layers combined can approach approximately 100% in desired angular and spectral ranges. In certain embodiments, the light turning element 602a, 602b and 602c can turn the incident light by approximately the same or different angles. In certain embodiments the light turning element 602a, 602b and 602c can comprise different surface relief diffraction features or holograms such that each of the three light turning elements collects different wavelengths of light. In certain embodiments, the different light guides 601a, 601b, and 601c can collect light of different wavelengths. In one embodiment, the stacked light guide can collect only those wavelengths of light that can be converted into electrical energy by a photocell (for e.g. visible wavelengths) while the ultraviolet (UV) and infrared (IR) radiation that can damage the photocell or light guide or holographic material is transmitted out of the light guide layers. The transmitted UV and IR radiation can be delivered to another element such as a heat generating element. Such a heat generating element may heat water, for example, to provide hot water or heat. In some embodiments, the water or other liquid, e.g., oil, may form steam. This steam may be used to drive one or more turbines and generate electricity. These methods of generating heat from solar radiation may be referred to as solar thermal generation. In various embodiments, the solar thermal generator may be used to heat a fluid e.g. water, oil or a gas to generate electrical and/or mechanical power.

FIG. 7 illustrates a composite light collector comprising light guide layers 701a, 701b and 701c that are stacked together without an air gap there between. Light turning element 702a, 702b and 702c are disposed on the upper surfaces of the light guide layers 701a, 701b and 701c. The light guides and the light turning elements can be laminated together. In some embodiments, all the light guides and the light turning elements can be optically coupled together as shown in FIG. 7 to form a single light guide. The light incident on the upper surface of the composite light guide can interact with any of the other light turning films or layers 702a, 702b and 702c and can be converted into guided modes of the light guide. One advantage of this method of stacking the light guides is that the overall thickness of the composite light guide layer can be reduced. In some embodiments, the overall thickness of such a composite light guide can be less than 1 cm although values outside this range are possible. For example, in one embodiment, if the composite light guide is laminated with air gaps then the thickness of the light guide can be greater than 1 cm. The thickness of each layer in a multi layer composite light guide may be approximately 1 mm. In some embodiments, the thickness of the light guide may be less than 0.5 mm. In some other embodiments, the thickness of the light guide may be less than 1 mm.

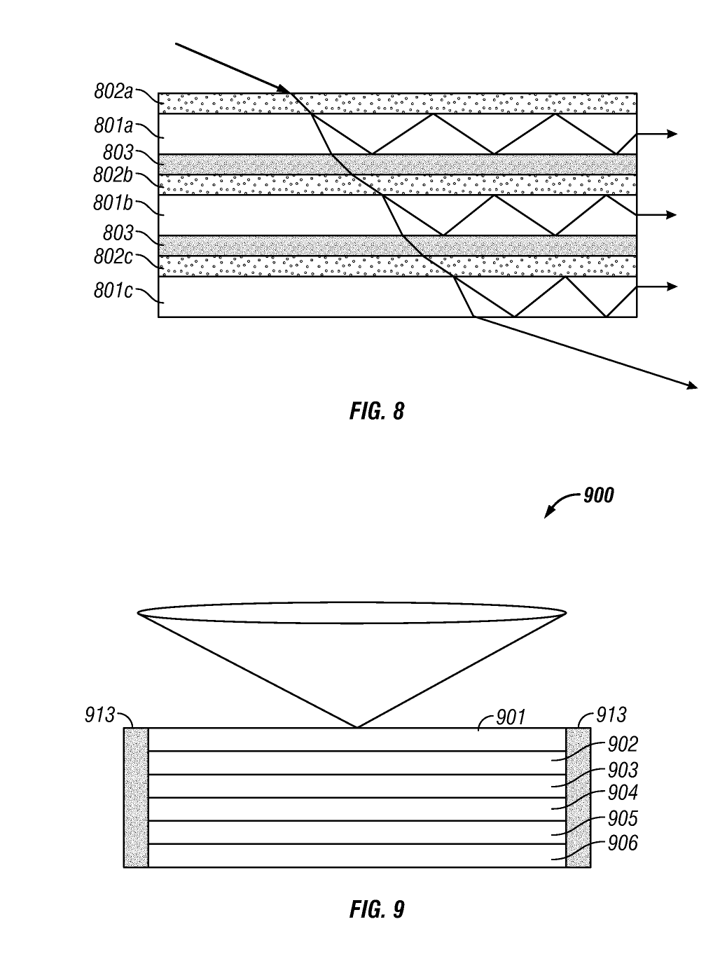

FIG. 8 shows a composite light collector comprising multiple light guides 801a, 801b and 801c. Each light guide 801a, 801b and 801c are separated by a layer of low refractive index material 803. The layer of low refractive index material 803 can be referred to as cladding in some embodiments. In various embodiments, the layer of low refractive index material 803 can optically isolate each light guide Thus, in some embodiments, the layer of low refractive index material 803 can be referred to as an optical isolation layer. The composite light collector further comprises light turning element (for e.g. 802a, 802b and 802c) disposed on the surface of the light guides 801a, 801b and 801c. As described above with reference to FIG. 6, a first portion of the light incident on the upper surface of the composite light guide is guided through the light guide 801a while a second portion of the light incident on the upper surface of the composite light guide is transmitted through the light guide 801a which is subsequently incident on the light guide 801b. A portion of the light incident on the upper surface of the stack of light guides is guided through the light guide 801b while another portion of the light incident on the light guide 801b is transmitted out of the light guide 801b and is subsequently incident on the light guide 801c. This process is repeated until a large portion of the light in a desired angular and/or spectral range is collected and guided by the composite light collector.

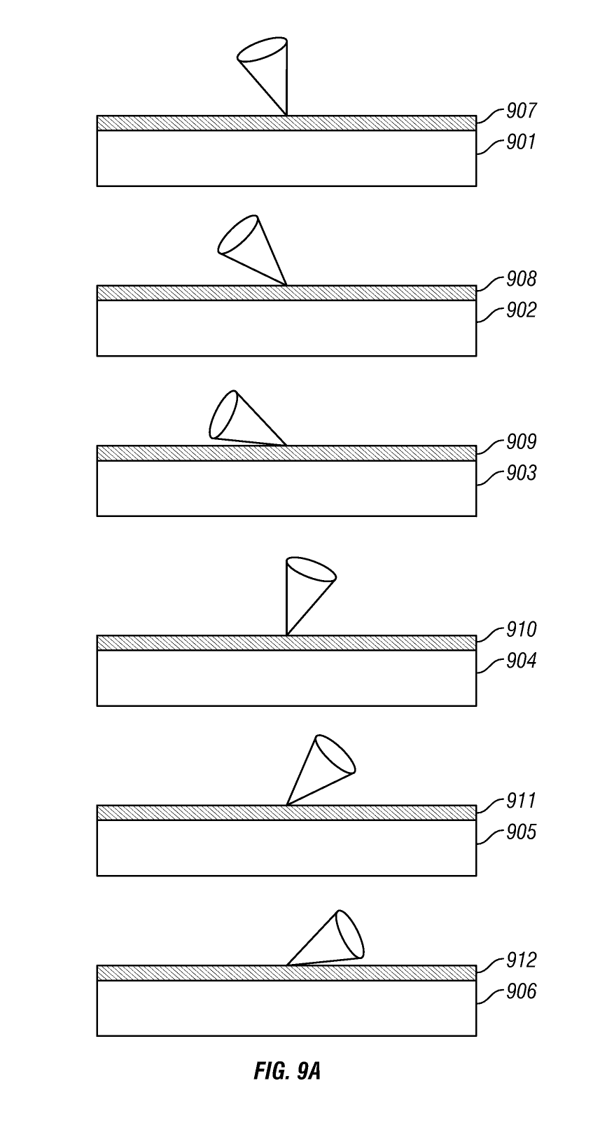

For every embodiment of the stacked composite light collector described above, the light collection efficiency can be further increased by designing each light turning element to capture or collect light in different angular cones as well as light in different spectral regions. This concept is described in detail below. In the embodiment 900 shown in FIG. 9, multiple light guide layers 901, 902, 903, 904, 905 and 906 are stacked together to form a composite light collecting structure. PV cells 913 can be disposed laterally with respect to the composite light collecting structure as shown in FIG. 9. Each light guide layer 901 through 906 further comprises a light turning element comprising diffraction features or holograms 907 through 912 as shown in FIG. 9A. The different light turning elements 907 through 912 are configured to capture light incident on the light collector from the surrounding medium (e.g. air) at different angles. For example, in one embodiment light turning element 907 can capture or collect rays of light that are incident between approximately 0 degrees and −15 degrees with respect to the normal to the light turning element 907. Light turning element 908 can collect rays of light that are incident between approximately −15 degrees and −30 degrees with respect to the normal to the light turning element 908. Whereas, light turning element 909 can collect rays of light that are incident between approximately −30 degrees and −45 degrees with respect to the normal to the light turning element 909. Light turning element 910 can collect rays of light that are incident between approximately 0 degrees and 15 degrees with respect to the normal to the light turning element 910. Light turning element 911 can collect rays of light that are incident between approximately 15 degrees and 30 degrees with respect to the normal to the light turning element 911 and light turning element 912 can collect rays of light that are incident between approximately 30 degrees and 45 degrees with respect to the normal to the light turning element 912. Thus the composite light collecting structure can effectively collect light that is incident between −45 degrees and 45 degrees with respect to the normal to the surface of the composite light guide. In some embodiments, the composite light collecting structure can effectively collect light between approximately −80 degrees and 80 degrees with respect to the normal to the surface of the composite light guide. In certain embodiments, the composite light collecting structure can effectively collect light between approximately ±70 degrees or ±60 degrees or ±50 degrees with respect to the normal to the surface of the composite light guide. The collection angles specified above are only examples. Other ranges for collection angles are possible in various other embodiments.

One possible advantage of stacking several light collecting layers each configured to collect different cones of light is that light can be efficiently collected through most of the day without mechanically changing the orientation of the light collectors. For example, in the morning and the evening, the rays of the sun are incident at grazing angles whereas at mid-day the rays of the sun are incident close to the normal. The embodiment described in FIG. 9 can collect light with approximately equal efficiency in the morning, afternoon and evening.

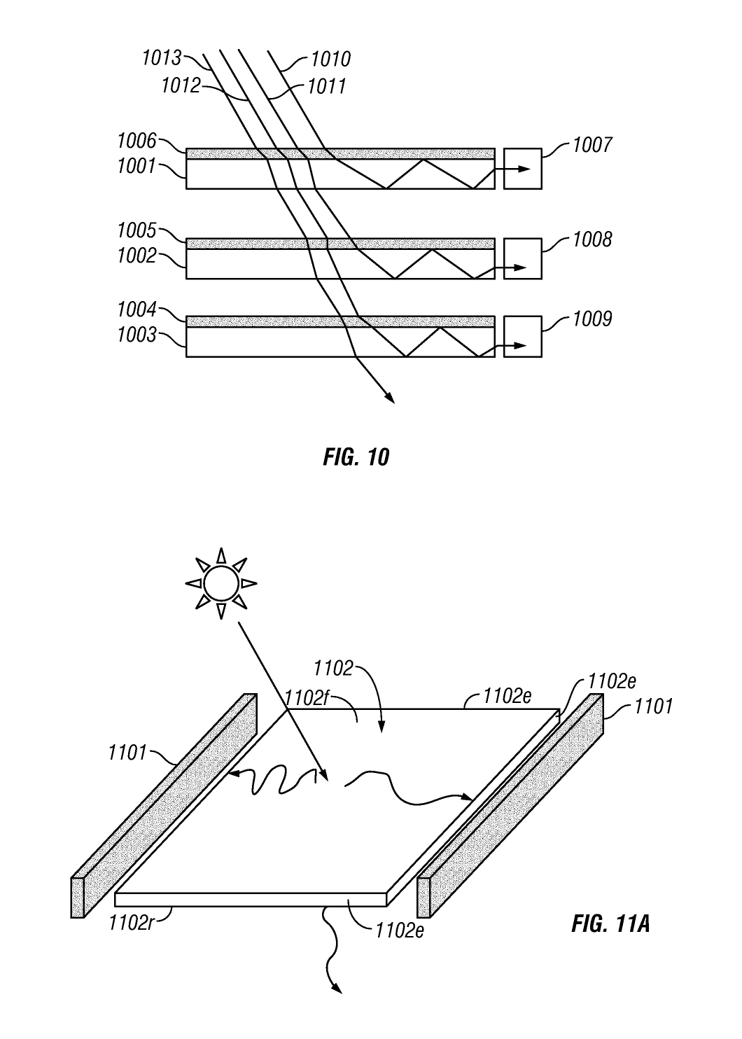

FIG. 10 shows an embodiment comprising multiple light guide layers 1001, 1002 and 1003 stacked together. Each light guide layer further comprises a light turning element 1004, 1005 and 1006, each comprising diffractive features or holograms. Photovoltaic (PV) cells 1007, 1008 and 1009 are disposed laterally with respect to each light guide layer 1001, 1002 and 1003. Each light turning element 1004, 1005 and 1006 is configured to collect light in a different spectral region that has an energy equivalent to the band gap of the corresponding PV cell. For example, as shown in FIG. 10, incident beam 1010 comprises light in the spectral range Δλ₁; incident beam 1011 comprises light in the spectral range Δλ₂; incident beam 1012 comprises light in the spectral range Δλ₃ and incident beam 1013 comprises light in the spectral range Δλ₄. In certain embodiments, the spectral ranges Δλ₁, Δλ₂ and Δλ₃ can correspond to blue, green and red light. Light turning element 1006 can efficiently collect light in the spectral range Δλ₁ and turn it into guided modes of the light guide 1001, directed towards the PV cell 1007. The band gap of the PV cell 1007 absorbs light efficiently in the spectral range Δλ₁. Similarly light turning elements 1005 and 1004 can efficiently collect light in the spectral ranges Δλ₂ and Δλ₃ and turn them into guided modes of light guides 1002 and 1003, directed towards PV cells 1008 and 1009 respectively. The band gap of the PV cells 1008 and 1009 absorbs light efficiently in the spectral range Δλ₂ and Δλ₃ respectively. Also shown in the embodiment illustrated in FIG. 10 is beam 1013 that comprises light in the spectral range Δλ₄ which is in the undesired spectral range (for e.g. IR or UV). The beam 1013 is not turned by any of the light turning elements 1004, 1005 and 1006 and is transmitted out.

As described herein, multiple light guides or light guide layers having different holographic layers or diffractive optical elements may be stacked. Although three light guide or light guide layers with three different holographic layers or diffractive optical elements are shown in FIGS. 6-8 and 10, more or less light guides or light guide layers with more or less different holographic layers or diffractive optical elements may be used. The same configuration need not be used throughout the stack. For example, air gaps can be used to separate some light guides while low index material can be used to separate other light guides. Additionally, light guide layers that are not optically isolated from each other can also be included with one or more light guides that are optically isolated. The use of multiple stacks can improve efficiency. The efficiency of multiple holographic layers, for example, is generally higher than the efficiency of multiple holograms recorded in a single layer. Accordingly, the amount of light diffracted by the hologram and coupled, for example, to a photocell may be increased.

In various embodiments, the light guide is thin, for example, less than a centimeter. The light guide may for example be less than 1 mm, 0.5 mm or 0.25 mm in certain embodiments. Accordingly, the light guide may be referred to as a thin film. Such thin films may comprise polymers or plastic. Such thin films may be light, flexible, inexpensive and easy to fabricate.

The light turning element comprising the diffractive features may also be thin, for example, less than 100 μm. The light turning element may for example be less than 50 μm, 10 μm or 1 μm in certain embodiments. Likewise the light turning element may be referred to as a thin film. Such thin films may comprise photosensitive material. For example, in one embodiment the light turning element may comprise holographic polymer from DuPont, Wilmington, Del.

In various embodiments, the light turning element is formed on a carrier which comprises the light guide. As described above this carrier may be a thin film less than a millimeter thick (e.g., less than 0.5 mm, 0.3 mm or 0.1 mm). Similarly, this carrier may comprise polymer or plastic and be flexible and inexpensive.

Holographic recording material may be coated onto the carrier and a hologram or diffractive optical element may be recorded in the coating. This coating may be developed in some embodiments to form the light turning features. In certain embodiments, a master may be used to form the light turning features in the coating on the carrier. Optical methods may be used in conjunction with the master to form the light turning features in the coating. Other methods such as embossing may also be used to form the light turning features from the master.

The master may, for example, be disposed on a drum and the carrier having the coating thereon may passed the rolling drum to create the diffractive features in the coating. In some embodiments, such a configuration is used in an embossing process. In some embodiments, a layer may be disposed over the diffractive features such as shown in FIG. 3C to planarize the surface and/or protect the diffractive features or for other reasons. The layer may comprise a low refractive index material having a lower refractive index than the light turning element in some embodiments.

To create a large master, a first master may be fabricated using optical methods via computer generation. Such a first master may, in some embodiments, comprise a wafer having features formed by photolithography and etching techniques. Other methods can be used to fabricate this first master. This master can used to produce a plurality of identical electroforms. These electroforms may be less than 12 inches in width and length in some embodiments. In some embodiments, the electroforms may be approximately 6 inches in width and length. The electroforms can be arranged in an array and mounted onto a substrate to produce a larger master. Such a master may include for example 10-20 such electroforms. The larger master can be used to fabricate large sheets having turning features therein. Embossing such as hot embossing, UV-embossing, etc., can be used. Other methods can also be employed. Such sheets can be greater than 1 meter wide in some embodiments. This approach enables large sheets to be produced without the need to use inordinately large optics such as lens, prisms, and/or mirrors.

In another embodiment, sheets of holographic features or diffractive turning features formed on a base film or carrier, which may comprise the light guide, are disposed on a common carrier film. This carrier film may be wider than the strips. In one embodiment, for example, the strips are 5-10 centimeters wide and are arranged on a carrier about 1 meter wide. Dimensions outside these ranges, however, are possible. Adhesive may be used to adhere the holographic or diffractive layer to the carrier film. Any or all of the layers, for example, the carrier, the adhesive, and the base film on which the holographic features or diffractive turning features are disposed may operate as the light guide and propagate and guide light therein.

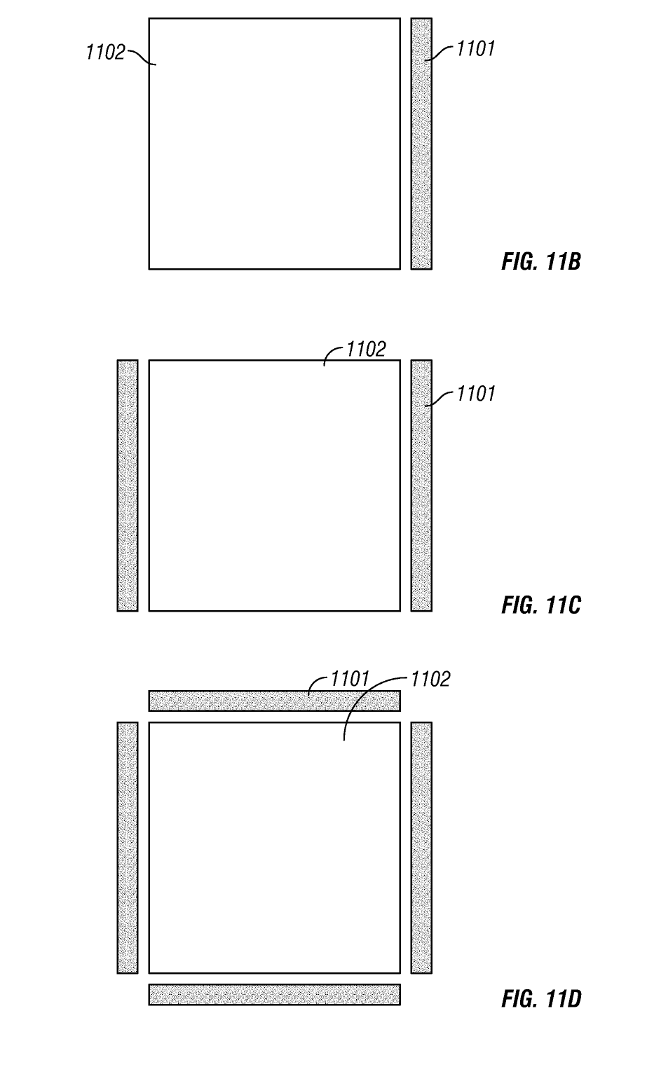

As described above, the light collectors can be integrated with a PV cell to capture sunlight and convert it into electricity. FIG. 11A shows a perspective view of PV cells 1101 integrated with a light collector 1102. The light collector 1102 comprises a forward surface 1102f and a rearward surface 1102r. The light collector 1102 further comprises a plurality of edges 1102e between the forward and the rearward surfaces 1102f, 1102r. The PV cells 1101 can be disposed laterally with respect to one or more of the plurality of edges 1102e as shown in FIG. 11A. The light collectors can be formed so as to capture and collect light at different angles of incidence and different wavelengths and direct the captured light towards one or more PV cells.

FIG. 11B shows the top view of an embodiment comprising a light collector 1102 and a PV cell 1101 disposed along one edge of the light collector 1102. FIG. 11C shows the top view of an embodiment, wherein two PV cells 1101 are disposed along two different edges of the light collector 1102 whereas FIG. 11D shows the top view of an embodiment, wherein four PV cells 1101 are disposed along four different edges of the light collector 1102. Other embodiments wherein more than four PV cells are disposed along one or more edges of the light collector are possible. The light collector can be designed such that different wavelengths of the incident light are directed towards different PV cells. In some embodiments, the PV cells may be disposed at one or more corners of the light collector 1102.

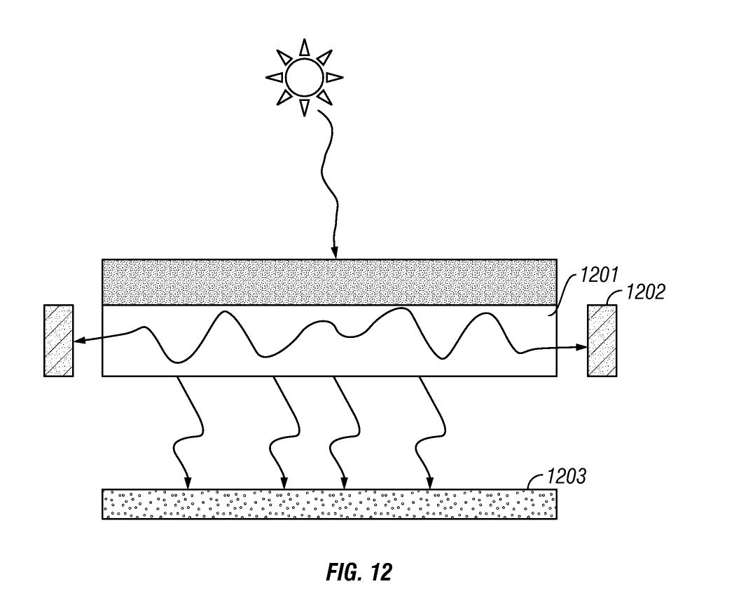

The undesired wavelengths of the incident light can be transmitted out of the light collector towards a solar thermal converter disposed rearward of the light collector as shown in FIG. 12. FIG. 12 shows the side view of a system that can generate heat and electricity from incident light. The embodiment shown in FIG. 12 comprises a light collector 1201. The light collector 1201 is composed of a light guide and a light turning layer having diffractive features or holograms. The embodiment shown in FIG. 12 further comprises PV cells 1202 disposed laterally with respect to the edges of the light collector 1201. A portion of the incident solar radiation is collected and guided by the light collector 1201 towards the PV cells 1202 where it is converted into electricity. The undesired spectral frequencies of the solar radiation (for e.g. UV and IR) are transmitted out of the light collector 1201 and directed towards a heat generating element 1203 (for e.g. solar thermal converter).

The method of using a light collecting plate, sheet or film comprising surface diffractive features or holograms to collect, concentrate and direct light to a photocell can be used to realize solar cells that have increased efficiency and can be inexpensive, thin, lightweight and environmentally stable and robust. The solar cells comprising of a light collecting plate, sheet or film coupled to a photocell may be arranged to form panels of solar cells. Solar cell panels formed using this approach can be lighter, environmentally stable and robust and upgraded with relative ease. For example as newer generation of more efficient PV cells become available, the older PV cells from these panels can be replaced by the newer PV cells. The light collecting plate, sheet or film can also be replaced with relative ease.

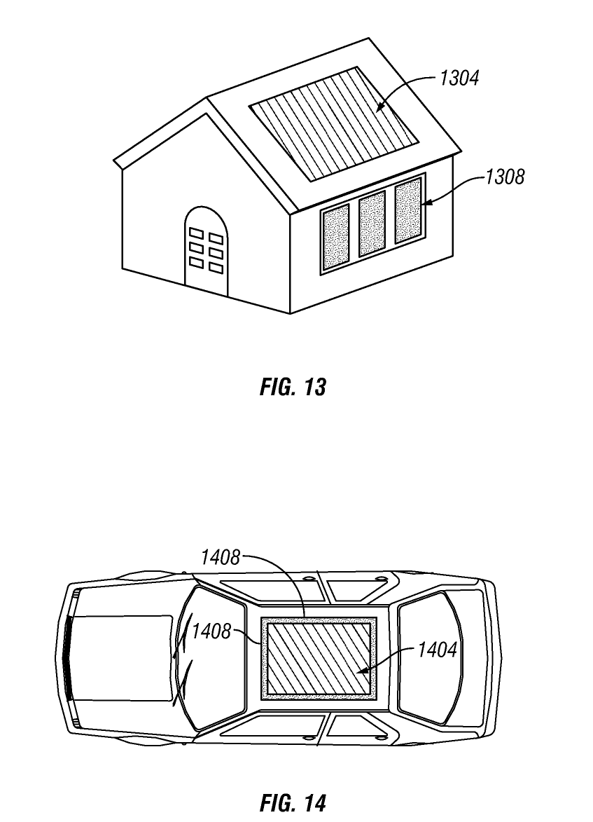

Such panels of solar cells can be used in a variety of applications. For example, a panel of solar cells comprising a plurality of light collectors optically coupled to PV cells and/or solar thermal generators may be mounted on the roof top of a residential dwelling or a commercial building or placed on doors and windows as illustrated in FIG. 13 to provide supplemental electrical power to the home or business. The light collectors may be formed of a transparent or semi-transparent plate, sheet or film. The light collectors may for example allow infrared radiation to pass through to the spatial region beneath the collector such as a roof top to heat a house or building or water pipes. The light collectors may comprise a light turning layer having reflection holograms that reflects a desired color (for example red or brown) for aesthetic purposes in addition to collecting or capturing incident light. The light collectors may be rigid or flexible. In some embodiments, the light collectors may be sufficiently flexible to be rolled. Solar cell panels comprising such sheets 1308 may be attached to window panes as shown in FIG. 13. The light collecting sheets may be transparent to see through the window. The light collecting sheets may, however, attenuate some of the light by redirecting light to PV cells. In some embodiments the light collecting sheets operate as a neutral density filter, attenuating transmission a substantially constant amount across the visible and possible invisible spectrum (e.g., infrared). Accordingly, such sheets may reduce glare in homes and buildings and lower temperatures therein. The light collecting sheets might alternatively be colored. In some embodiments, the light collectors may have wavelength filtering properties to filter out the ultraviolet radiation or other non-visible spectral components. In certain embodiments, the light collecting sheets can be used as window shades that can be rolled up or down or attached to window shades that roll up or down.

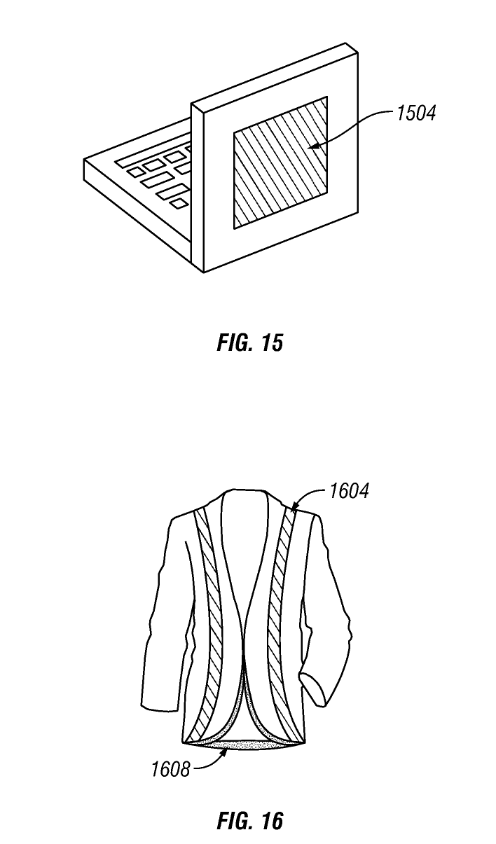

In other applications, light collectors may be mounted on cars and laptops as shown in FIGS. 14 and 15 respectively to provide electrical power. In FIG. 14, the light collecting plate, sheet or film 1404 is mounted to the roof of an automobile. Photocells 1408 can be disposed along the edges of the light collector 1404. The electrical power generated by the photocells can be used for example, to recharge the battery of a vehicle powered by gas, electricity or both or run electrical components as well. In FIG. 15, the light collecting plate, sheet or film 1504 may be attached to the body (for example external casing) of a laptop. This may be advantageous in providing electrical power to the laptop in the absence of electrical connection. Alternately, the light guiding collector optically coupled to photocells may be used to recharge the laptop battery.

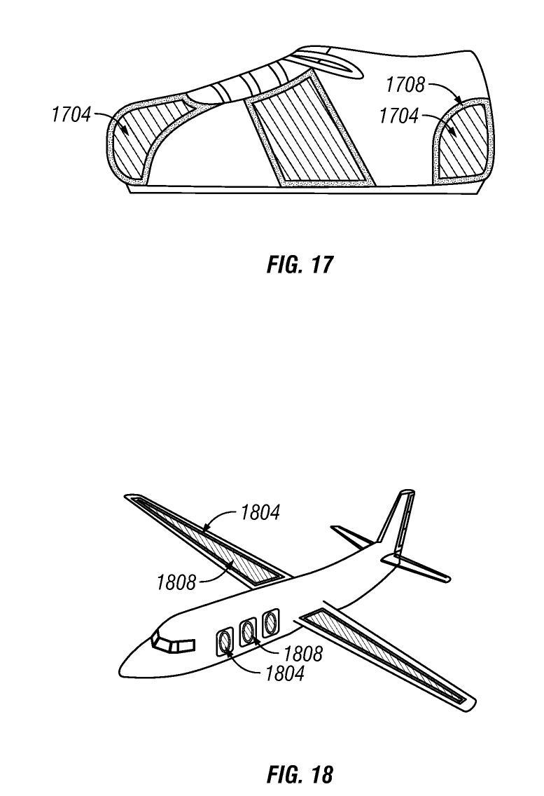

In some embodiments, the light collecting plate, sheet or film optically coupled to photocells may be attached to articles of clothing or shoes. For example FIG. 16 illustrates a jacket or vest comprising the light collecting plate, sheet or film 1604 optically coupled to photocells 1608 disposed around the lower periphery of the jacket or vest. In some embodiments, the photocells 1608 may be disposed elsewhere on the jacket or vest. The light collecting plate, sheet or film 1604 may collect, concentrate and direct ambient light to the photocells 1608. The electricity generated by the photocells 1608 may be used to power handheld devices such as PDAs, mp3 players, cell phone, etc. Alternately, the electricity generated by the photocells 1608 may be used to light the vests and jackets worn by airline ground crew, police, fire fighters and emergency workers in the dark to increase visibility. In another embodiment illustrated in FIG. 17, the light collecting plate, sheet or film 1704 may be disposed on a shoe. Photocells 1708 may be disposed along the edges of the light collecting plate, sheet or film 1704.

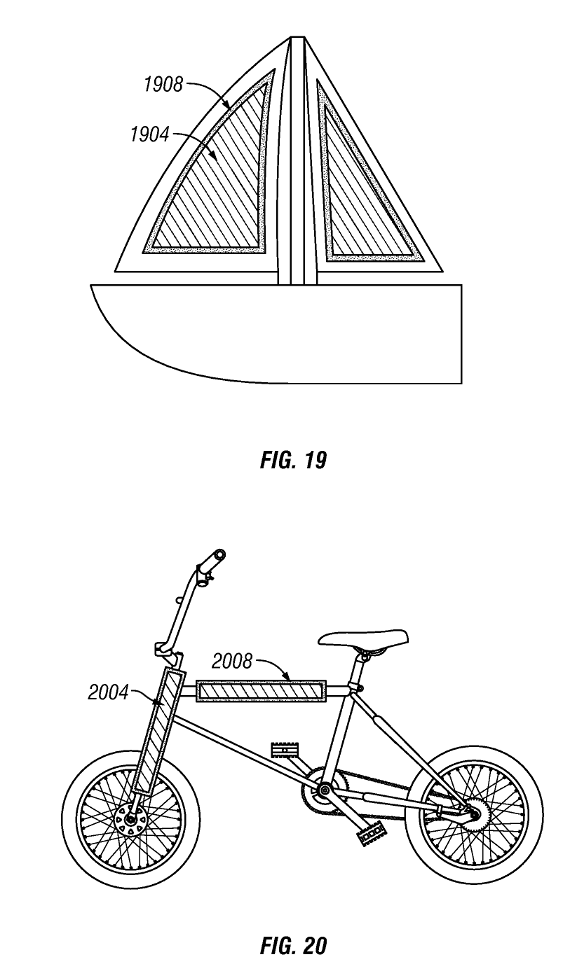

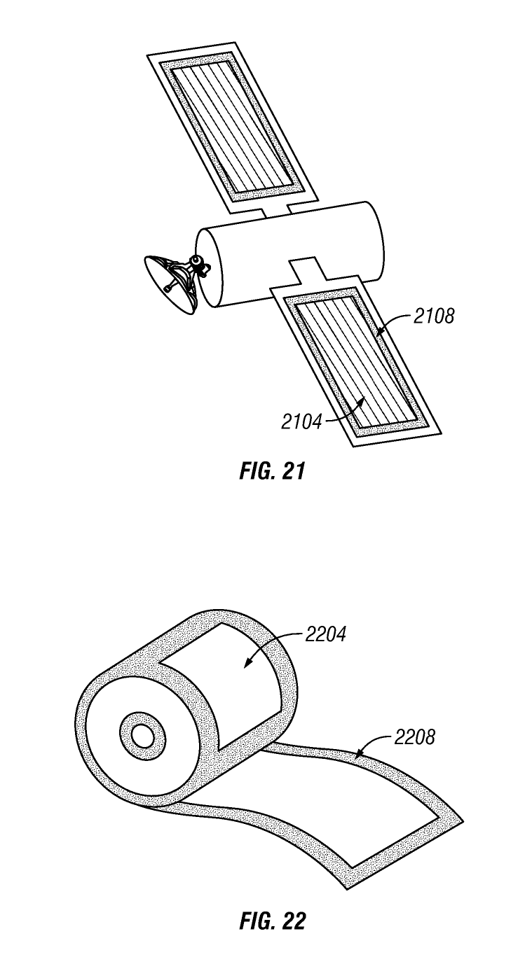

Panels of solar cells comprising light collecting plate, sheet or film having surface diffractive features or holograms coupled to photocells may be mounted on planes, trucks, trains, bicycles, sailboats, satellites and other vehicles and structures as well. For example as shown in FIG. 18, light collecting plate, sheet or film 1804 may be attached to the wings of an airplane or window panes of the airplane. Photocells 1808 may be disposed along the edges of the light collecting plate, sheet or film as illustrated in FIG. 18. The electricity generated may be used to provide power to parts of the aircraft. FIG. 19 illustrates the use of light collectors coupled to photocells to power navigation instruments or devices in a sail boat for example, refrigerator, television and other electrical equipments. The light collecting plate, sheet or film 1904 is attached to the sail of a sail boat. PV cells 1908 are disposed at the edges of the light collecting plate, sheet or film 1904. In alternate embodiments, the light collecting plate, sheet or film 1904 may be attached to the body of the sail boat for example, the cabin hull or deck. Light collecting plate, sheet or film 2004 may be mounted on bicycles as shown in FIG. 20. FIG. 21 illustrates yet another application of the light collecting plate, sheet or film optically coupled to photocells to provide power to communication, weather and other types of satellites. The light collector plate, sheet, or film may be used for other applications as well.

FIG. 22 illustrates a light collecting sheet 2204 that is sufficiently flexible to be rolled. The light collecting sheet is optically coupled to photocells. The embodiment described in FIG. 22 may be rolled and carried on camping or backpacking trips to generate electrical power outdoors and in remote locations where electrical connection is sparse. Additionally, the light collecting plate, sheet or film that is optically coupled to photocells may be attached to a wide variety of structures and products to provide electricity.

The light collecting plate, sheet or film optically coupled to photocells may have an added advantage of being modular. For example, depending on the design, the photocells may be configured to be selectively attachable to and detachable from the light collecting plate, sheet or film. Thus existing photocells can be replaced periodically with newer and more efficient photocells without having to replace the entire system. This ability to replace photocells may reduce the cost of maintenance and upgrades substantially.

A wide variety of other variations are also possible. Films, layers, components, and/or elements may be added, removed, or rearranged. Additionally, processing steps may be added, removed, or reordered. Also, although the terms film and layer have been used herein, such terms as used herein include film stacks and multilayers. Such film stacks and multilayers may be adhered to other structures using adhesive or may be formed on other structures using deposition or in other manners.

The examples described above are merely exemplary and those skilled in the art may now make numerous uses of, and departures from, the above-described examples without departing from the inventive concepts disclosed herein. Various modifications to these examples may be readily apparent to those skilled in the art, and the generic principles defined herein may be applied to other examples, without departing from the spirit or scope of the novel aspects described herein. Thus, the scope of the disclosure is not intended to be limited to the examples shown herein but is to be accorded the widest scope consistent with the principles and novel features disclosed herein. The word “exemplary” is used exclusively herein to mean “serving as an example, instance, or illustration.” Any example described herein as “exemplary” is not necessarily to be construed as preferred or advantageous over other examples.

1. A device for collecting solar energy comprising:
first and second light guide layers guiding light therein;
a first photocell;
a first plurality of diffractive features disposed to redirect ambient light incident on said first light guide layer; and
a second plurality of diffractive features disposed to redirect ambient light incident on said second light guide layer,
wherein light is guided in said first and second light guide layers to said first photocell.

2. The device of claim 1, wherein said first and second light guide layers comprises plastic.

3. The device of claim 3, wherein said plastic comprises acrylic, polycarbonate, polyester or cyclo-olefin polymer.

4. The device of any of claims 1, wherein said first photocell comprises a photovoltaic cell.

5. The device of claim 1, wherein said first photocell is butt-coupled to an edge of said first light guide.

6. The device of claim 1, wherein said first photocell is disposed at a corner of said first light guide.

7. The device of claim 1, wherein said first plurality of diffractive features is separated from said second plurality of diffractive features.

8. The device of claim 1, wherein said first plurality of diffractive features is separated from said second plurality of diffractive features.

9. The device of claim 1, wherein each of said first and second light guide layers are at least 1 cm².

10. The device of claim 1, wherein said first and second light guides are flexible.

11. The device of claim 1, wherein said first and second light guide layers comprises thin films.

12. The device of claim 1, wherein said first and second light guide layers each have a thickness less than 500 microns.

13. The device of claim 1, wherein said first and second plurality of diffractive features are each disposed in separate layers that are each between 1 μm and 100 μm thick.

14. The device of claim 1, wherein said first and second plurality of diffractive features are each disposed in separate layers, said separate layers separated by at least about 100 microns.

15. The device of claim 1, wherein said first plurality of diffractive features are disposed at a forward surface of the first light guide.

16. The device of claim 1, wherein said first plurality of diffractive features are disposed at a rearward surface of the first light guide.

17. The device of claim 1, wherein said first plurality of diffractive features comprises volume features.

18. The device of claim 1, wherein said first plurality of diffractive features comprises surface relief features.

19. The device of claim 1, wherein said first and second plurality of diffractive features are formed in first and second separate holographic layers.

20. The device of claim 19, wherein said first and second separate holographic layers comprises transmission holograms.

21. The device of claim 19, wherein said first and second separate holographic layers comprises reflection holograms.

22. The device of claim 19, wherein said first and second separate holographic layers comprises a reflection hologram and a transmission hologram.

23. The device of claim 1, further comprising an air gap between said first and second light guide layers separating said first and second pluralities of diffraction features.

24. The device of claim 1, further comprising an optical isolation layer between said first and second light guide layers separating said first and second pluralities of diffraction features, said optical isolation layer having a lower refractive index than said first and second light guide layers.

25. The device of claim 1, wherein said first and second light guide layers form parts of a single light guide.

26. The device of claim 1, wherein said first and second light guide layers are laminated together.

27. The device of claim 1, wherein said first and second light guide layers are disposed on an automobile, aircraft, spacecraft, or nautical vessel.

28. The device of claim 1, wherein said first and second light guide layers are disposed on a bicycle, stroller, or trailer.

29. The device of claim 1, wherein said first and second light guide layers are disposed on an article of clothing.

30. The device of claim 29, wherein said first and second light guide layers are disposed on a shirt, pants, shorts, coat, jacket, vest, hat, or footwear.

31. The device of claim 1, wherein said first and second light guide layers are disposed on a computer, a cell phone, or a personal digital assistant.

32. The device of claim 1, wherein said first and second light guide layers are disposed on an architectural structure.

33. The device of claim 32, wherein said first and second light guide layers are disposed on a house or building.

34. The device of claim 1, wherein said first and second light guide layers are disposed on an electrical device.

35. The device of claim 34, wherein said first and second light guide layers are disposed on a light, phone, or motor.

36. The device of claim 1, wherein said first and second light guide layers are disposed on a tent or a sleeping bag.

37. The device of claim 1, wherein said first and second light guide layers are rolled-up or folded.

38. A method of fabricating a device for collecting solar energy, the method comprising:
providing first and second light guide layers guiding light therein, said first light guide layer including a first plurality of diffractive features therein and said second light guide layer including a second plurality of diffractive features therein;
providing a first photocell;
wherein light is guided in said first and second light guide layers to said first photocell.

39. The method of claim 38, wherein providing a first photocell comprises butt coupling the first photocell to an edge of the first light guide.

40. The method of claim 38, wherein providing a first photocell comprises disposing the first photocell at a corner of the first light guide.

41. The method of claim 38, wherein the first plurality of diffractive features are disposed on the first light guide layer and wherein the second plurality of diffractive features are disposed on the second light guide layer

42. The method of claim 38, wherein the first plurality of diffractive features is embossed on said first light guide and said second plurality of diffractive features is embossed on said second light guide.

43. A device for collecting solar energy comprising:
first and second means for guiding light;
a first means for absorbing light, said light absorbing means configured to produce an electrical signal as a result of light absorbed by the light absorbing means;
a first plurality of means for diffracting light, said light diffracting means configured to redirect ambient light incident on said first light guiding means; and
a second plurality of means for diffracting light, said light diffracting means configured to redirect ambient light incident on said second light guiding means,
wherein light is guided in said first and second light guiding means to said first light absorbing means.

44. The device of claim 43, wherein the first and second light guiding means comprises light guide layers, the first light absorbing means comprises a photocell or the plurality of light diffracting means comprises diffractive features.

45. A device for collecting solar energy comprising:
at least one light collector, said light collector comprising a light guide having a top and bottom surface and a plurality of diffractive features configured to redirect ambient light incident on said top surface of said light guide;
at least one photocell; and
a solar thermal generator.

46. The device of claim 45, wherein said at least one light collector can collect ambient light with an incident angle lying between approximately −45 degrees and 45 degrees with respect to the normal to the surface of said light collector.

47. The device of claim 45, wherein said at least one light collector can collect ambient light with an incident angle lying between approximately −30 degrees and 30 degrees with respect to the normal to the surface of said light collector.

48. The device of claim 45, wherein said at least one light collector can collect ambient light with an incident angle lying between approximately −15 degrees and 15 degrees with respect to the normal to the surface of said light collector.

49. The device of claim 45, wherein said at least one photocell is disposed laterally with respect to said at least one light collector.

50. The device of claim 45, wherein said solar thermal generator is disposed rearward of said at least one light collector.

51. The device of claim 45, wherein ambient light in a first spectral range is directed towards said at least one photocell and ambient light in a second spectral range is directed towards said solar thermal generator.

52. The device of claim 45, wherein said at least one light collector is configured to transmit infrared radiation to said solar thermal generator.

53. A device for collecting solar energy comprising:
at least one means for collecting light, said light collecting means comprising a means for guiding light, said light guiding means having a top and bottom surface and a plurality of means for diffracting light, said light diffracting means configured to redirect ambient light incident on said top surface of said light guiding means;
at least one means for absorbing light, said light absorbing means configured to produce an electrical signal as a result of light absorbed by the light absorbing means; and
a means for converting thermal energy into electrical or mechanical energy.

54. The device of claim 53, wherein said light collecting means comprises a light collector, said light guiding means comprises a light guide, said light diffracting means comprises diffractive features, said absorbing means comprises a photocell, or said thermal energy converting means comprises a solar thermal generator.

55. A method of manufacturing a device for collecting solar energy, the method comprising:
providing at least one light collector, said light collector comprising a light guide having a top and bottom surface and a plurality of diffractive features configured to redirect ambient light incident on said top surface of said light guide;
providing at least one photocell; and
providing a solar thermal generator.

56. The method of claim 55, wherein the plurality of diffractive features are disposed on said light guide.

57. The method of claim 55, wherein the plurality of diffractive features are embossed on said light guide.
